(19) United States
(12) Patent Application Publication
(10) Pub. No.: US 2026/0183811 A1
(43) Pub. Date: Jul. 2, 2026

(54) SUBSTRATE PROCESSING APPARATUS

(71) Applicant: SEMES CO., LTD., Cheonan-si (KR)

(72) Inventors: Ho Jin JANG, Cheonan-si (KR); Doo Seop YOON, Daejeon (KR)

(21) Appl. No.: 19/344,971

(22) Filed: Sep. 30, 2025

(30) Foreign Application Priority Data
Dec. 31, 2024 (KR) 10-2024-0201753

(51) Int. Cl. B08B 15/02; B08B 9/08; H01L 21/67

(52) U.S. Cl. CPC B08B 15/02; B08B 9/08; B08B 2209/08; H10P 72/0404

(57) ABSTRACT

The present disclosure provides a substrate processing apparatus including a processing container in which a substrate is disposed; a cleaning unit disposed at least partially in an upper end portion of the processing container and supplying a cleaning liquid to the processing container; an exhaust line having a first end portion connected to the processing container, having a second end portion extended to an external side of the processing container, and discharging gas in the processing container externally; a fume-collecting unit including a fume collector collecting fumes included in the gas while the gas passes through the exhaust line; and a connection line connecting the processing container and the exhaust line, and supplying at least a portion of the cleaning liquid supplied to the processing container, to the fume-collecting unit.

### CROSS-REFERENCE TO RELATED APPLICATION(S)

This application claims benefit of priority to Korean Patent Application No. 10-2024-0201753 filed on Dec. 31, 2024 in the Korean Intellectual Property Office, the disclosure of which is incorporated herein by reference in its entirety.

### BACKGROUND

### 1. FIELD

The present disclosure relates to a substrate processing apparatus.

### 2. DESCRIPTION OF RELATED ART

In order to manufacture a semiconductor device, a predetermined pattern should be formed on a substrate such as a wafer. When a predetermined pattern is formed on a substrate, a deposition process, a lithography process, an etching process, or the like may be continuously performed.

In a lithography process, a photoresist used in the process generally has high viscosity, and due to such high viscosity, the photoresist applied to the substrate may fall onto and adhere to an upper surface of a middle bowl as well as an inner wall of a bowl. To solve this problem, periodic cleaning of the bowl may be performed.

In addition, large amounts of fumes may be generated when the substrate is processed using the photoresist having high viscosity, and such fumes may be discharged together through an exhaust line. However, in a process of exhausting gas containing fumes, there may be a problem that the fumes are stacked in a balance damper, which may be a vortex generation section in the exhaust line, and a periphery therearound, causing the exhaust line to be clogged.

### SUMMARY

The purpose of the present disclosure is to provide a substrate processing apparatus capable of collecting fumes from gas, when the gas containing the fumes is exhausted through an exhaust line, to prevent accumulation of the fumes in the exhaust line or clogging of the exhaust line due to the accumulation of the fumes.

A substrate processing apparatus according to an embodiment of the present disclosure includes a processing container in which a substrate is disposed; a cleaning unit disposed at least partially in an upper end portion of the processing container and supplying a cleaning liquid to the processing container; an exhaust line having a first end portion connected to the processing container, having a second end portion extended to an external side of the processing container, and discharging gas in the processing container externally; a fume-collecting unit including a fume collector collecting fumes included in the gas while the gas passes through the exhaust line; and a connection line connecting the processing container and the exhaust line, and supplying at least a portion of the cleaning liquid supplied to the processing container, to the fume-collecting unit.

A substrate processing apparatus according to an embodiment of the present disclosure includes a processing chamber in which a processing space is provided; a processing container disposed in the processing space to surround a substrate supported on a support portion; a cleaning unit disposed at least partially in the processing container and supplying a cleaning liquid to the processing container; an exhaust line having a first end portion connected to the processing container, having a second end portion extended to an external side of the processing container, and discharging gas in the processing container externally; a fume-collecting unit including a fume collector collecting fumes included in the gas while the gas passes through the exhaust line; and a connection line connecting the processing container and the exhaust line, and supplying at least a portion of the cleaning liquid supplied to an internal space of the processing container, to the fume-collecting unit.

A substrate processing apparatus according to an embodiment of the present disclosure includes a processing chamber in which a processing space is provided; a processing container disposed in the processing space to surround a substrate supported on a support portion; a nozzle portion disposed above the processing container and applying a processing liquid to the substrate; a cleaning unit supplying a cleaning liquid cleaning the processing container, and including a cleaning liquid-discharging portion disposed in an upper end portion of the processing container to discharge the cleaning liquid into the processing container, and a cleaning liquid-supplying line connecting a cleaning liquid-supplying source and the cleaning liquid-discharging portion and supplying the cleaning liquid to the cleaning liquid-discharging portion; an exhaust line having a first end portion connected to the processing container, having a second end portion extended to an external side of the processing container, and discharging gas in the processing container externally; a fume-collecting unit disposed in an internal space of the exhaust line and including a fume collector collecting fumes included in the gas discharged through the exhaust line; and a connection line connecting the processing container and the exhaust line, including a discharge portion connected to the exhaust line to discharge the cleaning liquid into the internal space of the exhaust line, and supplying at least a portion of the cleaning liquid supplied to an internal space of the processing container, to the fume-collecting unit, wherein the cleaning liquid-discharging portion is provided as a plurality of cleaning liquid-discharging portions, and the plurality of cleaning liquid-discharging portions are disposed to form at least one row in a circumferential direction of the processing container, wherein the fume collector includes a rotating shaft portion rotatable in one direction, and a rotating member protruding outwardly from the rotating shaft portion in a radial direction, provided in plural, and disposed to be spaced apart in a circumferential direction of the rotating shaft portion, wherein the cleaning liquid discharged from the cleaning liquid-discharging portion cleans the processing container, falls to a bottom surface of the processing container, and is then supplied to the discharge portion through the connection line, wherein the discharge portion is disposed in an upper end portion of one side of the rotating member, and discharges the cleaning liquid onto the rotating member to rotate the rotating member in one direction, and wherein, during a process of exhausting the gas through the exhaust line, the fumes included in the gas are collected and removed by the cleaning liquid supplied to the fume collector.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a view of a substrate processing apparatus viewed from above.

FIG. 2 is a view of the substrate processing apparatus of FIG. 1, viewed in direction A-A.

FIG. 3 is a view of the substrate processing apparatus of FIG. 1, viewed in direction B-B.

FIG. 4 schematically illustrates a substrate processing apparatus including a fume-collecting unit according to an embodiment of the present disclosure.

FIG. 5 illustrates an embodiment of a portion of the processing container and the cleaning liquid-discharging portion, viewed in direction I-I′ of FIG. 4.

FIG. 6 illustrates another embodiment of a portion of the processing container and the cleaning liquid-discharging portion, viewed in direction I-I′ of FIG. 4.

FIG. 7 is an enlarged view illustrating a portion of the fume-collecting unit according to an embodiment of the present disclosure, disposed in region A1 of FIG. 4.

FIG. 8 is an enlarged view illustrating a portion of the fume-collecting unit according to another embodiment of the present disclosure, disposed in region A1 of FIG. 4.

FIG. 9 illustrates a first state of the substrate processing apparatus including the fume-collecting unit of FIG. 4.

FIG. 10 illustrates a second state of the substrate processing apparatus including the fume-collecting unit of FIG. 4.

FIG. 11 is an enlarged view of region A2 of FIG. 10 in the substrate processing apparatus according to an embodiment of the present disclosure.

FIG. 12 illustrates a third state of the substrate processing apparatus including the fume-collecting unit of FIG. 4.

### DETAILED DESCRIPTION

Hereinafter, preferred embodiments may be described in detail with reference to the accompanying drawings such that those skilled in the art may easily implement the present disclosure. However, in describing the preferred embodiment of the present disclosure in detail, when it is determined that a detailed description of a related known function or configuration may unnecessarily obscure the gist of the present disclosure, the detailed description thereof may be omitted. In addition, the same reference numerals may be used throughout the drawings for components that perform similar functions and actions. In addition, in the present specification, terms such as ‘on,’ ‘upper portion,’ ‘upper side,’ ‘upward,’ ‘upward direction,’ ‘upper surface,’ ‘upper wall,’ ‘below,’ ‘lower portion,’ ‘lower side,’ ‘downward,’ ‘downward direction,’ ‘lower surface,’ ‘lower wall,’ or the like may be based on the drawings, and terms such as ‘in,’ ‘into,’ ‘internal portion’ ‘out of,’ ‘outside of,’ ‘external portion’ or the like may be based on an outer periphery of a component of interest, and may be actually changed, depending on a direction in which an element or a component is disposed.

In addition, throughout the specification, being able to ‘comprise’ or ‘include’ a component may mean that another component may be further included rather than excluding another component unless specifically opposed thereto.

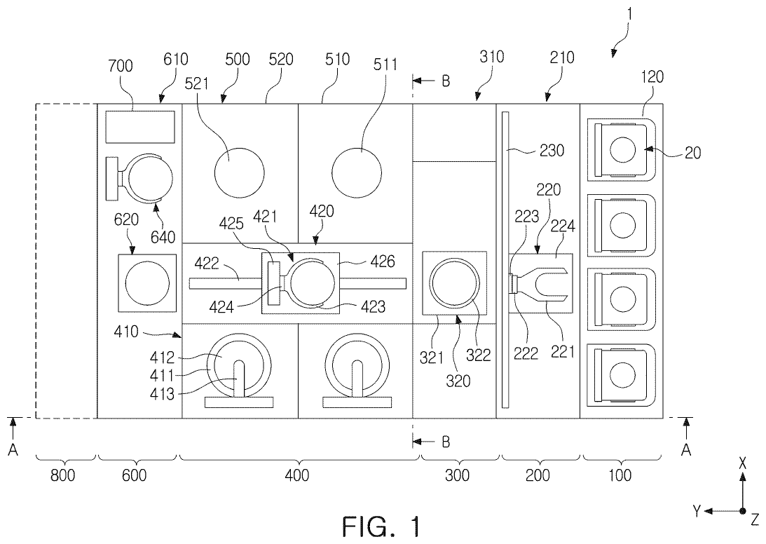

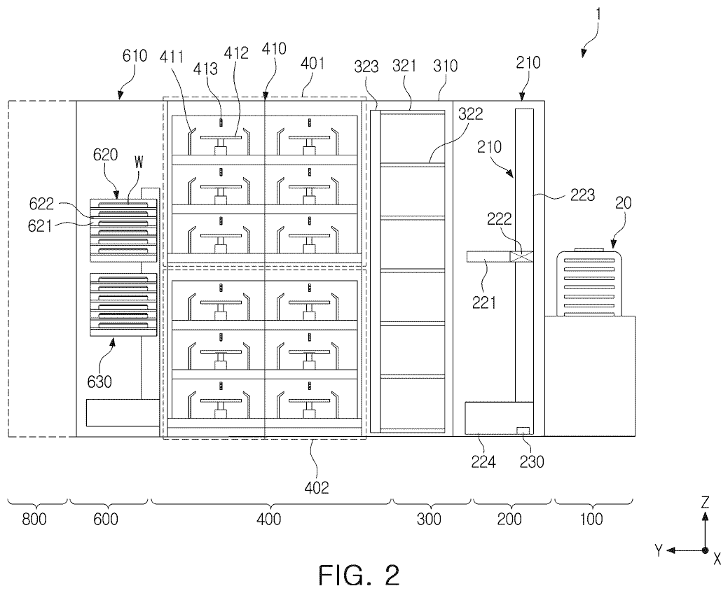

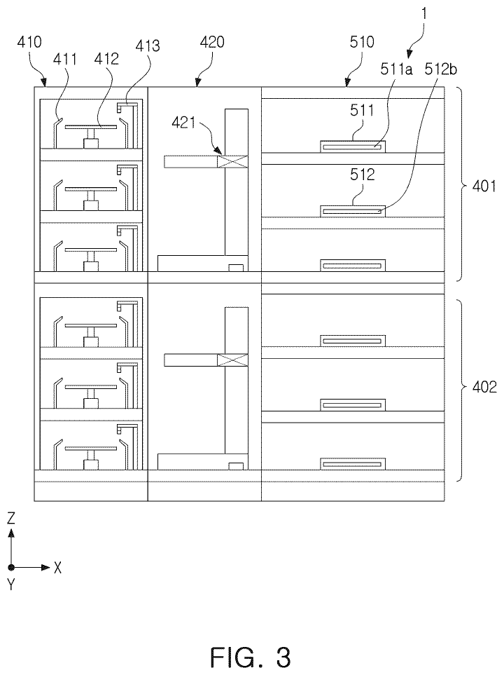

FIG. 1 is a view of a substrate processing apparatus viewed from above. FIG. 2 is a view of the substrate processing apparatus of FIG. 1, viewed in direction A-A. FIG. 3 is a view of the substrate processing apparatus of FIG. 1, viewed in direction B-B.

Referring to FIGS. 1 to 3, a substrate processing apparatus 1 may include a loading port 100, an index module 200, a buffer module 300, an applying/development module 400, and a purge module 700. The loading port 100, the index module 200, the buffer module 300, the applying/development module 400, and an interface module 600 may be sequentially disposed in a line in one direction. The purge module 700 may be provided in the interface module 600. Alternatively, the purge module 700 may be provided at various positions such as a position to which an exposure device at a rear end of the interface module 600 is connected, a side portion of the interface module 600, or the like.

Hereinafter, a direction in which the loading port 100, the index module 200, the buffer module 300, the applying/development module 400, and the interface module 600 are disposed may be referred to as a first direction Y, a direction, perpendicular to the first direction Y, may be referred to as a second direction X, and a direction, perpendicular to the first direction Y and the second direction X, may be referred to as a third direction Z, respectively.

A substrate W may be moved in a state accommodated in a cassette 20. The cassette 20 may have a structure that may be sealed from the outside. For example, a front opening unified pod (FOUP) having a door in a front portion may be used as the cassette 20.

The loading port 100 may include a mounting table 120 on which the cassette 20 in which the substrate W is accommodated is disposed. The mounting table 120 may be provided as a plurality of mounting tables 120, and the mounting tables 120 may be disposed in a row in the second direction X. Although FIG. 2 illustrates an example in which four mounting tables 120 are provided, the number thereof may be changed.

The index module 200 may transfer the substrate W between the buffer module 300 and the cassette 20 disposed on the mounting table 120 of the loading port 100. The index module 200 may include a module body 210, an index robot 220, and a guide rail 230.

The module body 210 may generally have a rectangular parallelepiped shape having an empty internal portion, and may be formed by connecting a plurality of frames. The module body 210 may be disposed between the loading port 100 and the buffer module 300. In this case, the module body 210 may be provided at a lower height than a frame 310 of the buffer module 300.

The index robot 220 and the guide rail 230 may be disposed in the module body 210. The index robot 220 may be a portion for returning the substrate W, and may include a hand body 221, an arm 222, and an elevation unit 223. Also, the index robot 220 may further include a support portion 224.

The hand body 221 may directly handle the substrate W. In this case, the hand body 221 may be provided to be movable in the first direction Y, the second direction X, and the third direction Z. Also, the hand body 221 may be provided to be rotatable. The hand body 221 may be fixedly installed on the arm 222. In this case, the arm 222 may be provided in a stretchable structure and a rotatable structure.

The elevation unit 223 may extend in the third direction Z. In this case, one end of the arm 220 may be fixedly coupled to the hand body 221, and the other end of the arm 222 may be connected to the elevation unit 223 to be elevated in the third direction Z. A lower end portion of the elevation unit 223 may be fixedly coupled to the support portion 224.

The guide rail 230 may extend in the second direction X. The support portion 224 may be coupled to the guide rail 230. In this case, the support portion 224 may linearly move in the second direction X along the guide rail 230. Also, although not illustrated in the drawings, the module body 210 may include a door opener to open or close a door of the cassette 20.

A ‘device for transferring the substrate W’ including the index robot 220, as described above, may be referred to as a transfer module TU, and a detailed description thereof will be described later.

The buffer module 300 may include a frame 310 and a buffer 320. Also, the buffer module 300 may further include a cooling chamber (not illustrated).

The frame 310 may be provided in a rectangular parallelepiped shape having an empty internal portion. The buffer module 300 may be disposed between the index module 200 and the applying/development module 400. The buffer 320 and the cooling chamber may be located in the frame 310.

Although not illustrated in the drawings, the buffer 320 may be provided as two or more buffers 320. In this case, one of the buffers 320 may be located at a height corresponding to an application module 401 of the applying/development module 400, and the other one of the buffers 320 and the cooling chamber may be provided at a height corresponding to a development module 402 of the applying/development module 400. Specific features of the buffer 320 will be described in detail below.

Cooling chambers may cool the substrate W, respectively. The cooling chamber may include a housing (not illustrated) and a chilling plate (not illustrated). The chilling plate may have an upper surface on which the substrate W is disposed, and a cooling means (not illustrated) cooling the substrate W. As the cooling means, various methods such as cooling by cooling water, cooling by using a thermoelectric element, or the like may be used.

Further, a lift pin assembly positioning the substrate W on the chilling plate may be provided in the cooling chamber. To carry the substrate W in or out of the chilling plate by a developing unit robot provided to the index robot 220 and the development module 402, the housing may have an opening in a direction in which the index robot 220 is provided and in a direction in which the developing unit robot is provided. Also, doors configured to open and close the above-described opening may be provided in the cooling chamber.

Although the buffer module 300 has been described in an embodiment including the cooling chamber, the present disclosure is not limited thereto, and a configuration of the cooling chamber may be omitted as necessary.

The application module 401 may include a process of applying a photosensitive solution such as a photoresist to the substrate W, and a heat processing process such as heating and cooling the substrate W before and after a resist coating process. The application module 401 may include an application chamber 410, a heat treatment chamber portion 500, and a transfer chamber 420. The application chamber 410, the transfer chamber 420, and the heat treatment chamber portion 500 may be sequentially disposed in the second direction X. For example, with respect to the transfer chamber 420, the application chamber 410 may be provided on one side of the transfer chamber 420, and the heat treatment chamber portion 500 may be provided on the other side of the transfer chamber 420.

The application chamber 410 may be provided as a plurality of application chambers 410, and the plurality of application chambers 410 may be provided, respectively, in the third direction Z. Also, as illustrated in FIG. 1, the application chamber 410 may be provided in plural or as one, in the first direction Y. The heat treatment chamber portion 500 may include a baking chamber 510 and a cooling chamber 520, and the baking chamber 510 and the cooling chamber 520 may be provided in plural, respectively, in the third direction Z. The transfer chamber 420 may be located in parallel with the buffer 320 of the buffer module 300 in the first direction Y. An application unit robot 421 and a guide rail 422 may be located in the transfer chamber 420. The transfer chamber 420 may have a substantially rectangular shape. The application unit robot 421 may transfer the substrate W between the baking chamber 510, the cooling chamber 520, the application chamber 410, and the buffer 320 of the buffer module 300.

The guide rail 422 may be disposed such that a length direction thereof is parallel to the first direction Y. The guide rail 422 may guide the application unit robot 421 to move linearly in the first direction Y. The application unit robot 421 may have a hand 423, an arm 424, a support 425, and a support portion 426. The hand 423 may be fixedly installed on the arm 424. The arm 424 may be provided in an elastic structure such that the hand 423 moves in a horizontal direction. The support 425 may be provided such that a length direction thereof is disposed in the third direction Z. The arm 424 may be coupled to the support 425 to move linearly in the third direction Z along the support 425. The support 425 may be fixedly coupled to the support portion 426, and the support portion 426 may be coupled to the guide rail 422 to be movable along the guide rail 422.

All of the application chambers 410 may have the same structure, but types of processing liquids used in each application chamber 410 may be different from each other. As a processing liquid, a processing liquid for forming a photoresist film or an antireflection film may be used.

The application chamber 410 may apply a processing liquid onto the substrate W. A treatment unit including a processing container 411, a support portion 412, and a nozzle portion 413 may be provided in the application chamber 410.

For example, one treatment unit may be disposed in each application chamber 410 in the first direction Y, but the present disclosure is not limited thereto, and two or more treatment units may be disposed in one application chamber 410. All of the treatment units may have the same structure. However, types of processing liquids used in each of the treatment units may be different from each other.

The processing container 411 of the application chamber 410 may have a shape in which an upper portion is opened. The support portion 412 may be disposed in the processing container 411, and may support the substrate W. The support portion 412 may be rotatably provided. The nozzle portion 413 may supply the processing liquid onto the substrate W disposed on the support portion 412. The processing liquid may be applied to the substrate W in a spin-coat manner. Additionally, the application chamber 410 may be optionally provided with a nozzle (not illustrated) supplying a cleaning liquid such as deionized water (DIW) to clean a surface of the substrate W to which the processing liquid is applied, and a back rinse nozzle (not illustrated) to clean a lower surface of the substrate W.

The baking chamber 510 may heat-treat the substrate W, when the substrate W is seated by the application unit robot 421.

In the baking chamber 510, a pre-bake process of heating the substrate W by a predetermined temperature, before applying a processing liquid, to remove organic matter or moisture from a surface of the substrate W, a soft bake process performed after applying a processing liquid on the wafer W, or the like may be performed. In addition, after a heating process is performed in the baking chamber 510, a cooling process for cooling the substrate W, or the like, may be performed.

A base portion B and a heating plate 511 may be disposed in the baking chamber 510.

The heating plate 511 may be a support plate on which the substrate W supplied into the baking chamber 510 is supported. The heating plate 511 may be provided with a heating means 511a. The heating plate 511 may be disposed on the base portion B.

The heating means 511a may heat the substrate W disposed in the baking chamber 510. The substrate W may be heated in a state in which the baking chamber 510 is sealed. The heating means 511a may heat an entire region of the substrate W to a uniform temperature. In this case, a plurality of support pins (not illustrated) protruding in an upward direction may be provided on an upper surface of the heating plate 511, and a heat processing process may be performed in a state in which the substrate W is supported on a support pin. Such a heat processing process may blow an organic material onto a liquid film formed by applying the processing liquid on the substrate W, to stabilize the liquid film.

Furthermore, the baking chamber 510 may further include a chilling plate 512. The chilling plate 512 may include at least one cooling means for cooling the substrate W. The chilling plate 512 may cool the substrate W by the cooling means, thereby preventing the substrate W from being heated to an excessively high temperature due to the heat processing process. The cooling means will be described in detail below.

The substrate W on which the heat processing process is completed may be transported to the cooling chamber 520. In the cooling chamber 520, a cooling process of cooling the substrate W may be performed before applying the processing liquid. The cooling chamber 520 may include a chilling plate 521. The chilling plate 521 may be a cooling means for cooling the substrate W, and various methods such as cooling by cooling water, cooling using a thermoelectric element, or the like may be used.

The interface module 600 may connect the applying/development module 400 to an exposure device 800 externally. The interface module 600 may include an interface frame 610, a first interface buffer 620, a second interface buffer 630, and a transfer robot 640, and the transfer robot 640 may return a substrate returned to the first and second interface buffers 620 and 630 to the exposure device 800, after an operation of the applying/development module 400 is completed. The first interface buffer 620 may include a housing 621 and a support 622, and the transfer robot 640 and the application unit robot 421 may load/unload the substrate W into/out the support 622.

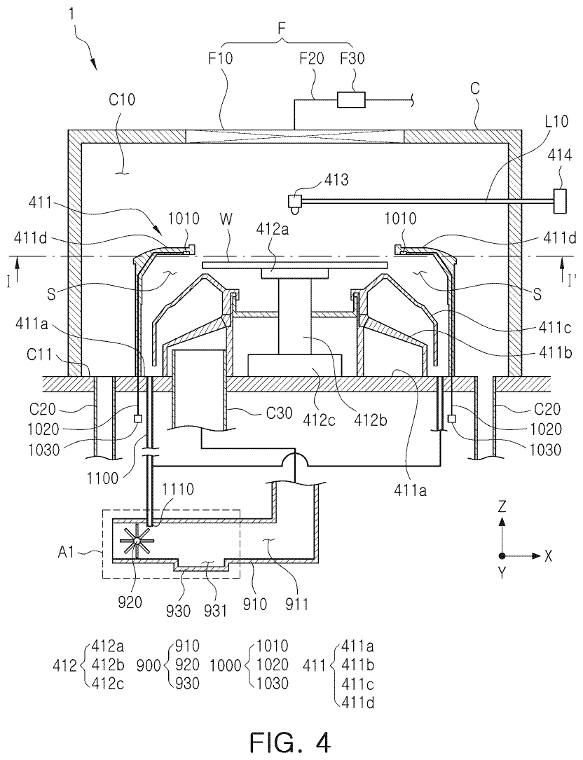

FIG. 4 schematically illustrates a substrate processing apparatus including a fume-collecting unit according to an embodiment of the present disclosure.

Referring to FIG. 4, a substrate processing apparatus 1 may include a processing chamber C, a processing container 411, a support portion 412, a fume-collecting unit 900, a cleaning unit 1000, and a connection line 1100. Further, the substrate processing apparatus 1 may further include a nozzle portion 413 and a gas flow generator F.

The processing chamber C may include a processing space C10 therein. In the processing space C10, various processing processes (hereinafter, a substrate processing process) may be performed on a substrate W. The processing chamber C may be an application chamber 410 applied to a photo processing process, but is not limited thereto. As another example, the processing chamber C may be a chamber applicable to various processes such as an etching process, a cleaning process, or the like.

The gas flow generator F may include a fan filter unit F10, a gas supply line F20, and a filter F30. The fan filter unit F10 may supply gas into the processing chamber C to generate a flow of the gas. To this end, the fan filter unit F10 may be disposed in an upper end portion of the processing chamber C. The fan filter unit F10 may be connected to a gas supply source (not illustrated) through the gas supply line F20, to receive the gas.

The filter F30 may be disposed on the gas supply line F20. The filter F30 may filter a foreign substance included in the gas passing through the gas supply line F20 before being supplied to the fan filter unit F10. The gas passed through the filter F30 may be supplied into the processing space C10 through the fan filter unit F10. As described above, purified gas may be supplied to the processing chamber C through the fan filter unit F10, and thus a downward airflow from an upper portion to a lower portion may be formed in the processing space C10. A first exhaust unit C20 may be disposed on a bottom surface C11 of the processing chamber C. The first exhaust unit C20 may be connected to an exhaust means, such as a vacuum pump and the like, to exhaust the gas in the processing chamber C.

The support portion 412 may have a configuration supporting the substrate W, and may be disposed in the processing chamber C. In this case, the support portion 412 may be disposed in the processing space C10 to support the substrate W. The support portion 412 may include a rotating chuck 412a rotating the substrate W in a state in which the substrate W is supported on an upper surface thereof, and a driver 412c driving the rotating chuck 412a to rotate about a rotating shaft 412b. The rotating chuck 412a may rotate, together with the substrate W, about the rotating shaft 412b by driving the driver 412c, in a state in which the substrate W is fixed on an upper surface thereof.

Although not illustrated in the drawings, the support portion 412 may include a plurality of support pins (not illustrated). A support pin may be raised and lowered by a support pin driver (not illustrated). In a state in which the support pin is raised, the substrate W may be received from a transfer robot such as an application unit robot 421 or the like. When a lower surface of the substrate W is seated on the plurality of support pins, the substrate W may be lowered by the support pin driver (not illustrated) such that transfer of the substrate W onto the support portion 412 may be completed. In this manner, when transfer of the substrate W to an upper surface of the rotating chuck 412a is completed, the rotating chuck 412a may rotate together with the substrate W, as described above.

In a state of rotating the substrate W, various processing liquids may be supplied to the substrate W through the nozzle portion 413, and thus the substrate W may be processed. The nozzle portion 413 may be connected to a processing liquid-supplying source 414 through a first supply line L10. The nozzle portion 413 may derive a processing liquid supplied from the processing liquid-supplying source 414 through the first supply line L10, to the substrate W.

The processing container 411 may be disposed to surround the support portion 412 and the substrate W, to recover the processing liquid supplied to the substrate W. The processing container 411 may include at least one cup.

For example, the processing container 411 may include a bottom surface 411a, a first cup 411b, a second cup 411c, and a third cup 411d. In this case, the first cup 411b may be disposed on the bottom surface 411a, and the second cup 411c may be disposed to surround the first cup 411b. Further, the third cup 411d may be provided to surround the second cup 411c to be disposed on an outermost side of the processing container 411. In this case, a separation space S may be formed between the second cup 411c and the third cup 411d. The processing liquid and a portion of the gas, applied to the substrate W, may flow through the separation space S.

The support portion 412 may be disposed in a central portion of the bottom surface 411a of the processing container 411. In this case, the support portion 412 may be inserted into an opening formed in the bottom surface 411a, and may be raised and lowered, as necessary.

Also, a second exhaust unit C30 exhausting gas may be disposed on the bottom surface 411a. When gas is supplied from the gas flow generator F to the processing chamber C, some of the gas may be introduced into a space between the processing container 411 and the substrate W, to be exhausted through the second exhaust unit C30 disposed on the bottom surface 411a of the processing container 411.

The second exhaust unit C30 may be connected to an exhaust line 910 discharging gas in the processing container 411 externally. The gas in the processing container 411 may sequentially pass through the second exhaust unit C30 and the exhaust line 910, and may be exhausted to an outside of the processing chamber C.

A discharge portion discharging the processing liquid supplied to the substrate W may be disposed on the bottom surface 411a of the processing container 411. In this case, the processing liquid supplied to the substrate W through the nozzle portion 413 may flow into the space between the processing container 411 and the substrate W. In a process of flowing along a flow of the gas exhausted through the second exhaust unit C30, the processing liquid may be discharged through the discharge portion disposed on the bottom surface 411a of the processing container 411.

Fumes may be generated during the substrate processing process of applying the processing liquid in a high-temperature environment, and when such fumes are discharged together with the gas through the exhaust line 910, various problems may occur, such as threatening safety of a worker or contaminating other devices of the substrate processing apparatus 1. The fume-collecting unit 900 may collect fumes included in the gas exhausted externally through the exhaust line 910 to prevent the fumes from being discharged externally.

In an embodiment, the fume-collecting unit 900 may include an exhaust line 910 and a fume collector 920.

One end portion (hereinafter, referred to as a first end portion) of the exhaust line 910 may be connected to the second exhaust portion C30, and the other end portion (hereinafter, referred to as a second end portion) of the exhaust line 910 may extend to an outside of the process chamber C. In this case, the gas introduced into an internal space 911 of the exhaust line 910 through the first end portion connected to the second exhaust portion C30 may flow along the exhaust line 910 in an extending direction, and may be exhausted externally through the second end portion. In this case, the fume collector 920 may be disposed in the second end portion of the exhaust line 910.

The fume collector 920 may be rotatably disposed in the second end portion of the exhaust line 910. For example, the fume collector 920 may be disposed to be adjacent to an opening formed in the second end portion of the exhaust line 910. The opening of the second end portion may be a path discharged to an outside of the exhaust line 910 flowing through the internal space 911. In this case, the fume collector 920 may include a rotating shaft portion 921 and a rotating member 922.

The rotating member 922 may be disposed to protrude from an outer surface of the rotating shaft portion 921 in a radial outward direction of the rotating shaft portion 921. The rotating member 922 may be provided as a plurality of rotating members 922. The plurality of rotating members 922 may be disposed on the outer surface of the rotating shaft portion 921 in a circumferential direction of the rotating shaft portion 921. As described above, when the rotating shaft portion 921 rotates in one direction (hereinafter, referred to as a rotation direction R), the plurality of rotating members 922 may rotate together in the same rotation direction R.

In another embodiment, the fume-collecting unit 900 may further include a stepped portion 930 preventing a backflow of a cleaning liquid.

The stepped portion 930 may be disposed between the processing container 411 and the fume collector 920. More specifically, the stepped portion 930 may be formed between the first end portion of the exhaust line 910 and the fume collector 920 in the internal space 911. In this case, the stepped portion 930 may be provided in a groove shape concave in a downward direction (−Z) from a bottom surface of the internal space 911 of the exhaust line 910. A portion of a cleaning liquid Th introduced into the internal space 911 may be accommodated in the stepped portion 930. Therefore, it is possible to prevent the cleaning liquid Th from backflowing in the exhaust line 910.

During the substrate processing process using the processing liquid, pollutants including some of the processing liquid discharged to the substrate W and fumes generated during the substrate processing process may flow into the separation space S. In this case, a portion of the pollutants may be scattered toward an inner side surface of the third cup 411d, and the other portion of the pollutants may be seated on an upper surface of the second cup 411c, such that the processing container 411 may be contaminated.

The cleaning unit 1000 may supply the cleaning liquid Th to clean the processing container 411 contaminated by pollutants, as described above. In this case, the cleaning unit 1000 may include a cleaning liquid-discharging portion 1010, a cleaning liquid-supplying line 1020, and a cleaning liquid-supplying source 1030.

The cleaning liquid-discharging portion 1010 may be disposed in an upper end portion of the processing container 411. The cleaning liquid-discharging portion 1010 may be disposed in some of a plurality of cups included in the processing container 411. More specifically, the cleaning liquid-discharging portion 1010 may be disposed in an outermost cup among the plurality of cups. For example, when the processing container 411 includes the first cup 411b, the second cup 411c, and the third cup 411d, as described above, the cleaning liquid-discharging portion 1010 may be disposed in the third cup 411d. Hereinafter, an embodiment in which the cleaning liquid-discharging portion 1010 is disposed in the third cup 411d will be mainly described, but the present disclosure is not limited thereto.

The cleaning liquid-discharging portion 1010 may be disposed in an upper end portion of the third cup 411d. More specifically, the cleaning liquid-discharging portion 1010 may be disposed on a lower surface of the upper end portion of the third cup 411d. In this case, the cleaning liquid-discharging portion 1010 may be provided in a through-hole shape to be connected to the cleaning liquid-supplying line 1020.

In the cleaning liquid-supplying line 1020, One end portion may be connected to the cleaning liquid-discharging portion 1010, and the other end portion may extend through an internal space of the third cup 411d. In this case, the other end portion of the cleaning liquid-supplying line 1020 may be connected to the cleaning liquid-supplying source 1030 disposed on an outside of the processing container 411. The cleaning liquid Th may be supplied from the cleaning liquid-supplying source 1030 to the cleaning liquid-discharging portion 1010 through the cleaning liquid-supplying line 1020.

The cleaning liquid Th may be discharged to a lower portion of the third cup 411d through the cleaning liquid-discharging portion 1010. A portion of the discharged cleaning liquid Th may move in a downward direction (−Z) along an inner side surface of the third cup 411d, and may remove contaminants attached to the inner side surface of the third cup 411d. A different portion of the discharged cleaning liquid Th may fall to an upper surface of the second cup 411c, may then move along the upper surface of the second cup 411c, and may remove contaminants deposited on the upper surface. The cleaning liquid Th obtained by washing the second cup 411c or the third cup 411d may move and fall to the bottom surface 411a of the processing container 411. In addition, another different portion of the discharged cleaning liquid Th may fall directly onto the bottom surface 411a of the processing container 411.

The connection line 1100 may connect the processing container 411 to the exhaust line 910. The connection line 1100 may supply the cleaning liquid Th, as described above, supplied into the processing container 411, to the fume-collecting unit 900.

One end (hereinafter, a first end portion) of the connection line 1100 may be inserted into and coupled to a through-portion formed on the bottom surface 411a of the processing container 411 to communicate with the separation space S. The other end (hereinafter, a second end portion) of the connection line 1100 may extend to an outside of the processing container 411, and may be connected to the exhaust line 910. As described above, the connection line 1100 may supply the cleaning liquid Th, which has moved to the bottom surface 411a of the processing container 411 after being discharged from the cleaning liquid-discharging portion 1010, to the internal space 911 of the exhaust line 910. For example, a pump may be connected to the connection line 1100 to move the cleaning liquid Th to the exhaust line 910.

In this case, a discharge portion 1110 discharging the cleaning liquid Th into the internal space 911 may be provided in the second end portion of the connection line 1100. The discharge portion 1110 may be inserted through a through-portion formed in an upper end portion of the second end portion of the exhaust line 910, and thus the connection line 1100 and the exhaust line 910 may be connected. The through-portion of the exhaust line 910 may be disposed in an upper end portion of one side of the fume collector 920. In this case, the one side of the fume collector 920 may be opposite to the second end portion of the exhaust line 910 among both sides of the fume collector 920, when the exhaust line 910 is viewed in a lateral direction (ZX plane direction).

Therefore, the discharge portion 1110 may discharge the cleaning liquid Th toward the fume collector 920 in a downward direction (−Z), in the upper end portion of one side of the fume collector 920. As described above, the cleaning liquid Th discharged through the discharge portion 1110 may be the cleaning liquid Th supplied from the bottom surface 411a of the processing container 411 through the connection line 1100.

The cleaning liquid Th discharged from the discharge portion 1110 may fall onto the rotating member 922 of the fume collector 920. As described above, since the rotating member 922 is pressed in a falling direction of the cleaning liquid Th by a force that the cleaning liquid Th falls, the rotating member 922 may rotate in a rotation direction R with respect to the rotating shaft portion 921.

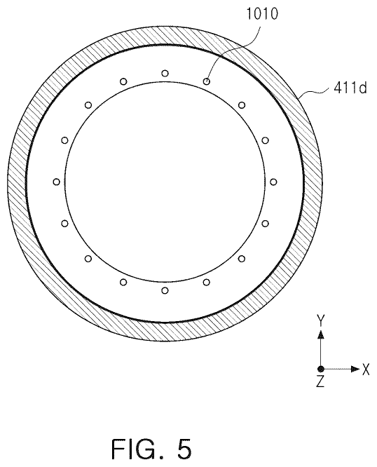

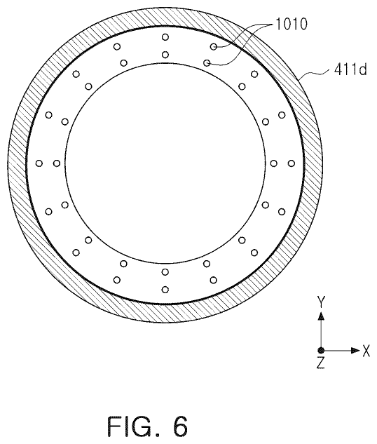

FIG. 5 illustrates an embodiment of a portion of the processing container and the cleaning liquid-discharging portion, viewed in direction I-I′ of FIG. 4. FIG. 6 illustrates another embodiment of a portion of the processing container and the cleaning liquid-discharging portion, viewed in direction I-I′ of FIG. 4.

Referring to FIGS. 5 and 6, a cleaning unit 1000 may include a plurality of cleaning liquid-discharging portions 1010. In this case, a plurality of cleaning liquid-supplying lines 1020 may be provided and connected to the cleaning liquid-discharging portions 1010 in a one-to-one manner, thereby supplying a cleaning liquid Th to each of the cleaning liquid-discharging portions 1010.

The plurality of cleaning liquid-discharging portions 1010 may be disposed in an upper end portion of a third cup 411d. In this case, the plurality of cleaning liquid-discharging portions 1010 may be disposed on a lower surface of the upper end portion of the third cup 411d, to discharge the cleaning liquid Th from the upper end portion of the third cup 411d in a downward direction (−Z).

In the case, the plurality of cleaning liquid-discharging portions 1010 may be disposed to be spaced apart from each other in a circumferential direction of a processing container 411. For example, as illustrated in FIG. 5, the plurality of cleaning liquid-discharging portions 1010 may be disposed to be spaced apart from each other in a row in the upper end portion of the third cup 411d in a circumferential direction of the third cup 411d. As another example, as illustrated in FIG. 6, the plurality of cleaning liquid-discharging portions 1010 may be disposed to be spaced apart from each other to form a plurality of rows in the upper end portion of the third cup 411d in a circumferential direction of the third cup 411d. However, the present disclosure is not limited thereto, and the cleaning liquid-discharging portions 1010 may be disposed in various forms, such as alternating arrangement and the like, with each other while forming a plurality of rows.

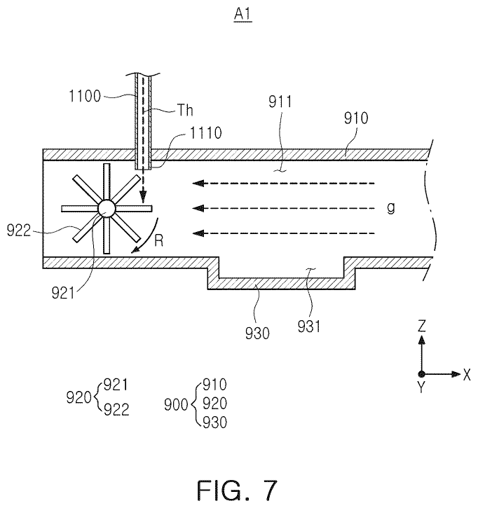

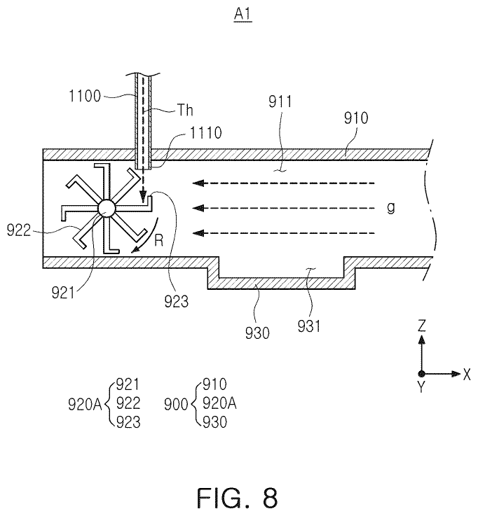

FIG. 7 is an enlarged view illustrating a portion of the fume-collecting unit according to an embodiment of the present disclosure, disposed in region A1 of FIG. 4. FIG. 8 is an enlarged view illustrating a portion of the fume-collecting unit according to another embodiment of the present disclosure, disposed in region A1 of FIG. 4.

Referring to FIG. 7, in a fume collector 920 according to an embodiment of the present disclosure (hereinafter, referred to as Example 1), a plurality of rotating members 922 may be disposed to be spaced apart from each other in a circumferential direction of a rotating shaft portion 921. In this case, the rotating member 922 may have a plate shape extending linearly. The plurality of rotating members 922 may have the same or similar length. For example, the fume collector 920 may have a shape in which the plurality of rotating members 922 are radially disposed with respect to the rotating shaft portion 921.

A cleaning liquid Th discharged from a discharge portion 1110 disposed in an upper end portion (e.g., a right upper end portion of the drawing) on one side of the fume collector 920 in a downward direction (−Z) may fall on an upper surface of any one of the plurality of rotating members 922. When the cleaning liquid Th falls on any one of the rotating members 922, potential energy may be converted into kinetic energy, and thus the rotating member 922 on which the cleaning liquid Th is seated may start to rotate in a rotation direction R. Thereafter, the plurality of rotating members 922 may be sequentially and continuously pressed in a downward direction (−Z) by the cleaning liquid Th supplied from the discharge portion 1110, such that the fume collector 920 may rotate in the rotation direction R.

In this case, gas exhausted from a processing space C10 moves from a first end portion of an exhaust line 910 to a second end portion of the exhaust line 910 through an internal space 911, and may pass through the fume collector 920 that rotates. In this process, gas g may meet the cleaning liquid Th supplied to the fume collector 920. In this case, while the gas g passes through the fume collector 920 and the cleaning liquid Th supplied thereto, fumes included in the gas g may be collected by the cleaning liquid Th, and may be removed therefrom. Thereafter, the gas from which fumes have been removed may pass through the second end portion of the exhaust line 910, and may be exhausted externally.

Referring to FIG. 8, in a fume collector 920A according to another embodiment of the present disclosure (hereinafter, referred to as Example 2), a plurality of rotating members 922 may be disposed to be spaced apart from each other in a circumferential direction of a rotating shaft portion 921. In the case of the fume collector 920A of Example 2, the rotating member 922 may include a bent portion 923.

The bent portion 923 may be disposed at an end portion (hereinafter, a protruding end portion) protruding radially outward of the rotating shaft portion 921 among both end portions of the rotating members 922. The bent portion 923 may be provided in a shape bent in a direction, perpendicular to a length direction of the rotating member 922, in the protruding end portion. For example, when the rotating member 922, which is rotating, faces a discharge portion 1110 in a vertical direction Z, the bent portion 923 may be bent in an upward direction (+Z), opposite to a downward direction (−Z), of a cleaning liquid Th. Therefore, the rotating member 922 including the bent portion 923 may have an ‘┐’ shape. The plurality of rotating members 922 having such a shape may be radially disposed around the rotating shaft portion 921, thereby forming the fume collector 920A.

As the bent portion 923 is provided as above, a protruding end portion of the rotating member 922 may be closed by the bent portion 923 in a radial outward direction. Therefore, the cleaning liquid Th may be stably seated on the rotating member 922 after being discharged from the discharge portion 1110. In addition, since the cleaning liquid Th seated on the rotating member 922 may be accommodated in a region partitioned by the bent portion 923 and the rotating member 922 for a predetermined time, an effect of rotating the rotating member 922, as described above, by pressing in a downward direction (−Z) may be improved.

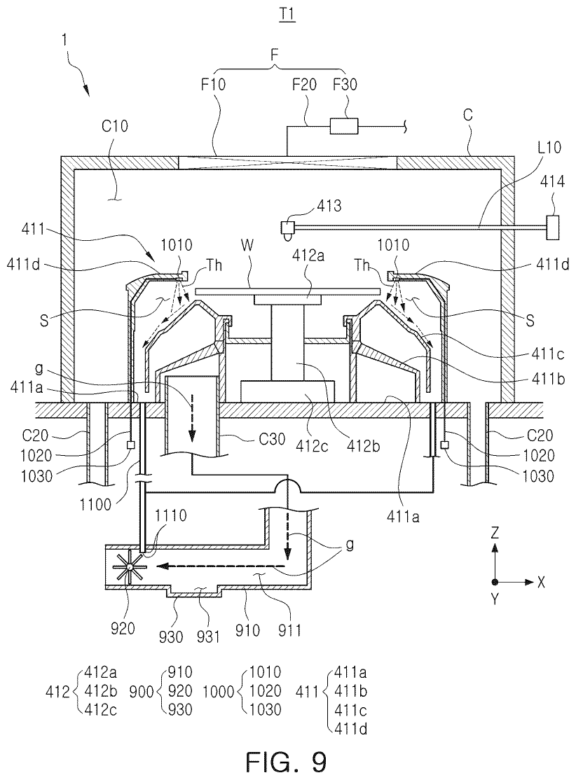

FIG. 9 illustrates a first state of the substrate processing apparatus including the fume-collecting unit of FIG. 4.

Referring to FIG. 9, when a processing process for the substrate W is completed by a processing liquid discharged through the nozzle portion 413, a cleaning process for cleaning the processing container 411 may be performed. Hereinafter, a state in which the processing container 411 may be cleaned by a cleaning liquid Th sprayed from the cleaning unit 1000 may be defined as a ‘first state T1’).

In the first state T1, the cleaning liquid Th may be discharged in a downward direction (−Z) from the cleaning liquid-discharging portion 1010 disposed in the upper end portion of the third cup 411d. A portion of the discharged cleaning liquid Th may move to the upper surface of the second cup 411c located at the lower side of the cleaning liquid-discharging portion 1010. Thereafter, the cleaning liquid Th may be lowered along the upper surface of the second cup 411c to clean contaminants on the upper surface of the second cup 411c. Although not illustrated in the drawing, the other portion of the discharged cleaning liquid Th may move in a downward direction (−Z) while removing contaminants adhering to the inner side surface of the third cup 411d.

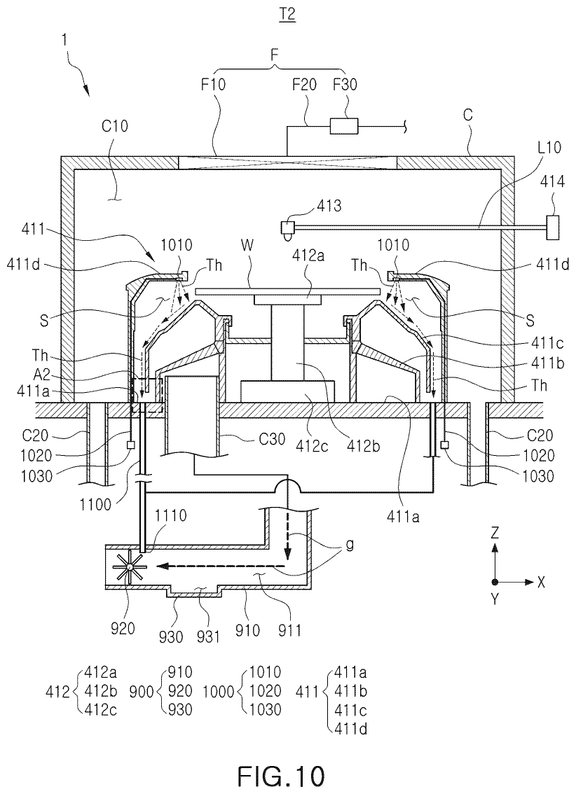

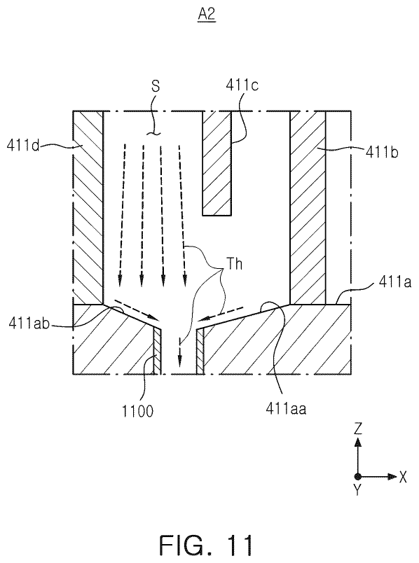

FIG. 10 illustrates a second state of the substrate processing apparatus including the fume-collecting unit of FIG. 4. Also, FIG. 11 is an enlarged view of region A2 of FIG. 10 in the substrate processing apparatus according to an embodiment of the present disclosure.

Referring to FIGS. 10 and 11, after cleaning the upper surface of the second cup 411c and the inner side surface of the third cup 411d in the first state T1 described above, the cleaning liquid Th may be lowered to the lower end portion of the processing container 411. In this manner, a state in which the cleaning liquid Th that has cleaned the processing container 411 falls on the bottom surface 411a may be defined as a ‘second state T2.’

In the second state T2, a portion of the cleaning liquid Th seated on the bottom surface 411a of the processing container 411 may move to the connection line 1100 connected to the bottom surface 411a. Also, the other portion of the cleaning liquid Th seated on the bottom surface 411a of the processing container 411 may be discharged to an outside of the processing container 411 through a discharge portion (not illustrated) formed on the bottom surface 411a.

In an embodiment, the bottom surface 411a of the processing container 411 may have a flat shape. In this case, a portion of the cleaning liquid Th seated on the bottom surface 411a may move along the flat bottom surface to be introduced into the connection line 1100.

In another embodiment, as illustrated in FIG. 11, the bottom surface 411a of the processing container 411 may include inclined surface portions 411aa and 411ab. For example, inclined surface portions 411aa and 411ab may be formed on both sides of the connection line 1100, with the connection line 1100 interposed therebetween. The inclined surface portions 411aa and 411ab may be provided to be inclined toward the connection line 1100. Hereinafter, for convenience of explanation, an inclined surface disposed on a right side of the connection line 1100 may be defined as a ‘first inclined surface portion 411aa’ based on the drawing, and an inclined surface disposed on a left side of the connection line 1100 may be defined as a ‘second inclined surface portion 411ab.’

In the case, the first inclined surface portion 411aa may be inclined such that a height of the bottom surface 411a may decrease toward the connection line 1100 from the lower end portion of the first cup 411b. In addition, the second inclined surface portion 411ab may be inclined such that a height of the bottom surface 411a may decrease toward the connection line 1100 from the lower end portion of the third cup 411d. In this manner, since the inclined surface portions 411aa and 411ab may be provided on both sides of the connection line 1100, the cleaning liquid Th falling to the bottom surface 411a through the separation space S may be induced to move to the connection line 1100 (or the discharge portion) by the first inclined surface portion 411aa or the second inclined surface portion 411ab.

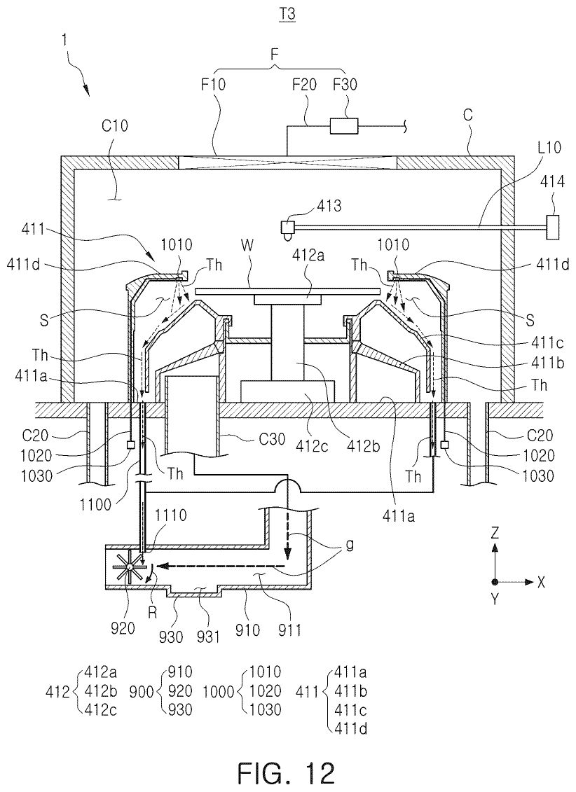

FIG. 12 illustrates a third state of the substrate processing apparatus including the fume-collecting unit of FIG. 4.

Referring to FIG. 12, the cleaning liquid Th introduced into the connection line 1100 may move to the exhaust line 910 through the connection line 1100. The cleaning liquid Th may be supplied to the internal space 911 of the exhaust line 910 through the discharge portion 1110 connected to the second end portion of the exhaust line 910. In this case, the cleaning liquid Th may be discharged from the discharge portion 1110 to fall toward the rotating member 922 of the fume collector 920, and the plurality of rotating members 922 may rotate in the rotation direction R by the falling cleaning liquid Th. In this process, the cleaning liquid Th may be sprayed in a direction toward the gas g moving toward the fume collector 920 through the exhaust line 910 by the rotating members 922, which is rotating.

In this manner, the fume collector 920 may rotate by the cleaning liquid Th supplied through the connection line 1100, and the cleaning liquid Th may be sprayed into the internal space 911 of the exhaust line 910 may be defined as a ‘third state T3.’

In the third state T3, the gas g exhausted along the exhaust line 910 may pass through the fume collector 920, which is rotating in a state of spraying the cleaning liquid Th into the internal space 911. In this process, the sprayed cleaning liquid Th and the gas g may meet, and fumes included in the gas g may be collected into the cleaning liquid Th.

Thereafter, the gas g from which fumes have been removed may be exhausted through the opening formed in the second end portion of the exhaust line 910. In this case, an airflow toward the outside of the exhaust line 910 may be formed in the second end portion of the exhaust line 910 in the internal space 911 by rotation of the fume collector 920 in the rotation direction R. By the airflow formed in this manner, the gas g from which fumes have been removed may be induced to be exhausted from the exhaust line 910.

In a substrate processing apparatus 1 according to embodiments of the present disclosure, as described above, in a process of discharging fumes generated during a substrate processing process using a photoresist having a high viscosity through an exhaust line 910 together with gas g, the fumes may be collected and removed by supplying a cleaning liquid Th used for cleaning a processing container 411 to the exhaust line 910. Therefore, even when the gas g containing fumes is discharged, it is possible to prevent the exhaust line 910 from being clogged due to accumulation of the fumes in the exhaust line 910.

A substrate processing apparatus according to embodiments of the present disclosure, in a process of discharging fumes generated during a substrate processing process using a photoresist having a high viscosity through an exhaust line together with gas, the fumes may be collected and removed by supplying a cleaning liquid used for cleaning a processing container to the exhaust line. Therefore, even when the gas containing fumes is discharged, it is possible to prevent the exhaust line from being clogged due to accumulation of the fumes in the exhaust line.

While example embodiments have been illustrated and described above, it will be apparent to those skilled in the art that modifications and variations could be made without departing from the scope of the present disclosure as defined by the appended claims.

What is claimed is:

1. A substrate processing apparatus comprising:
a processing container in which a substrate is disposed;
a cleaning unit disposed at least partially in the processing container and supplying a cleaning liquid to the processing container;
an exhaust line having a first end portion connected to the processing container, having a second end portion extended to an external side of the processing container, and discharging gas in the processing container externally;
a fume-collecting unit including a fume collector collecting fumes included in the gas while the gas passes through the exhaust line; and
a connection line connecting the processing container and the exhaust line, and supplying at least a portion of the cleaning liquid supplied to an internal space of the processing container, to the fume-collecting unit.

2. The substrate processing apparatus of claim 1, wherein the fume collector is disposed in an internal space of the exhaust line, and
the connection line includes a discharge portion connected to the exhaust line and discharging the cleaning liquid into the internal space of the exhaust line.

3. The substrate processing apparatus of claim 2, wherein the fume collector includes a rotating shaft portion rotatable in one direction, and a rotating member protruding outwardly from the rotating shaft portion in a radial direction.

4. The substrate processing apparatus of claim 3, wherein the rotating member is provided as a plurality of rotating members, and
the plurality of rotating members are disposed to be spaced apart in a circumferential direction of the rotating shaft portion.

5. The substrate processing apparatus of claim 3, wherein the rotating member includes a bent portion having one end fixedly coupled to the rotating shaft portion and the other end protruding outwardly in the radial direction and bent in a direction, inclined with respect to a length direction of the rotating member.

6. The substrate processing apparatus of claim 3, wherein the discharge portion is disposed above one side of the rotating member, and discharges the cleaning liquid onto the rotating member to rotate the rotating member in one direction.

7. The substrate processing apparatus of claim 1, wherein the cleaning unit includes a cleaning liquid-discharging portion disposed in an upper end portion of the processing container to discharge the cleaning liquid into the processing container, and a cleaning liquid-supplying line connecting a cleaning liquid-supplying source and the cleaning liquid-discharging portion and supplying the cleaning liquid to the cleaning liquid-discharging portion.

8. The substrate processing apparatus of claim 7, wherein the cleaning liquid-discharging portion is provided as a plurality of cleaning liquid-discharging portions, and
the plurality of cleaning liquid-discharging portions are disposed to form at least one row in a circumferential direction of the processing container.

9. The substrate processing apparatus of claim 1, wherein the exhaust line includes a stepped portion disposed between the fume collector and the processing container and having a groove shape concave downward from a bottom surface of the internal space of the exhaust line.

10. A substrate processing apparatus comprising:
a processing chamber in which a processing space is provided;
a processing container disposed in the processing space to surround a substrate supported on a support portion;
a cleaning unit disposed at least partially in the processing container and supplying a cleaning liquid to the processing container;
an exhaust line having a first end portion connected to the processing container, having a second end portion extended to an external side of the processing container, and discharging gas in the processing container externally;
a fume-collecting unit including a fume collector collecting fumes included in the gas while the gas passes through the exhaust line; and
a connection line connecting the processing container and the exhaust line, and supplying at least a portion of the cleaning liquid supplied to an internal space of the processing container, to the fume-collecting unit.

11. The substrate processing apparatus of claim 10, wherein the fume collector is disposed in an internal space of the exhaust line, and
the connection line includes a discharge portion connected to the exhaust line and discharging the cleaning liquid into the internal space of the exhaust line.

12. The substrate processing apparatus of claim 11, wherein the fume collector includes a rotating shaft portion rotatable in one direction, and a rotating member protruding outwardly from the rotating shaft portion in a radial direction.

13. The substrate processing apparatus of claim 12, wherein the rotating member is provided as a plurality of rotating members, and
the plurality of rotating members are disposed to be spaced apart in a circumferential direction of the rotating shaft portion.

14. The substrate processing apparatus of claim 12, wherein the discharge portion is disposed above one side of the rotating member, and discharges the cleaning liquid onto the rotating member to rotate the rotating member in one direction.

15. The substrate processing apparatus of claim 14, wherein the cleaning unit includes a cleaning liquid-discharging portion disposed in an upper end portion of the processing container to discharge the cleaning liquid into the processing container, and a cleaning liquid-supplying line connecting a cleaning liquid-supplying source and the cleaning liquid-discharging portion and supplying the cleaning liquid to the cleaning liquid-discharging portion.

16. The substrate processing apparatus of claim 15, wherein the cleaning liquid-discharging portion is provided as a plurality of cleaning liquid-discharging portions, and
the plurality of cleaning liquid-discharging portions are disposed to form at least one row in a circumferential direction of the processing container.

17. The substrate processing apparatus of claim 15, wherein the cleaning liquid discharged from the cleaning liquid-discharging portion cleans the processing container, falls to a bottom surface of the processing container, and then moves to the exhaust line through the connection line.

18. The substrate processing apparatus of claim 17, wherein, during a process of exhausting the gas through the exhaust line, the fumes included in the gas are collected and removed by the cleaning liquid supplied to the fume collector.

19. The substrate processing apparatus of claim 10, wherein the exhaust line includes a stepped portion disposed between the fume collector and the processing container and having a groove shape concave downward from a bottom surface of the internal space of the exhaust line.

20. A substrate processing apparatus comprising:
a processing chamber in which a processing space is provided;
a processing container disposed in the processing space to surround a substrate supported on a support portion;
a nozzle portion disposed above the processing container and applying a processing liquid to the substrate;
a cleaning unit supplying a cleaning liquid cleaning the processing container, and including a cleaning liquid-discharging portion disposed in an upper end portion of the processing container to discharge the cleaning liquid into the processing container, and a cleaning liquid-supplying line connecting a cleaning liquid-supplying source and the cleaning liquid-discharging portion and supplying the cleaning liquid to the cleaning liquid-discharging portion;
an exhaust line having a first end portion connected to the processing container, having a second end portion extended to an external side of the processing container, and discharging gas in the processing container externally;
a fume-collecting unit disposed in an internal space of the exhaust line and including a fume collector collecting fumes included in the gas discharged through the exhaust line; and
a connection line connecting the processing container and the exhaust line, including a discharge portion connected to the exhaust line to discharge the cleaning liquid into the internal space of the exhaust line, and supplying at least a portion of the cleaning liquid supplied to an internal space of the processing container, to the fume-collecting unit,
wherein the cleaning liquid-discharging portion is provided as a plurality of cleaning liquid-discharging portions, and the plurality of cleaning liquid-discharging portions are disposed to form at least one row in a circumferential direction of the processing container,
wherein the fume collector includes a rotating shaft portion rotatable in one direction, and a rotating member protruding outwardly from the rotating shaft portion in a radial direction, provided in plural, and disposed to be spaced apart in a circumferential direction of the rotating shaft portion,
wherein the cleaning liquid discharged from the cleaning liquid-discharging portion cleans the processing container, falls to a bottom surface of the processing container, and is then supplied to the discharge portion through the connection line,
wherein the discharge portion is disposed in an upper end portion of one side of the rotating member, and discharges the cleaning liquid onto the rotating member to rotate the rotating member in one direction, and
wherein, during a process of exhausting the gas through the exhaust line, the fumes included in the gas are collected and removed by the cleaning liquid supplied to the fume collector.
